(19) United States
(12) Patent Application Publication
(10) Pub. No.: US 2025/0204203 A1
(43) Pub. Date: Jun. 19, 2025

(54) DISPLAY DEVICE AND METHOD OF MANUFACTURING THE SAME

(71) Applicant: Samsung Display Co., LTD., Yongin-si (KR)

(72) Inventors: Jae Been LEE, Yongin-si (KR); Ju Won YOON, Yongin-si (KR); Seung Hwan CHO, Yongin-si (KR)

(21) Appl. No.: 18/817,917

(22) Filed: Aug. 28, 2024

(30) Foreign Application Priority Data
Dec. 14, 2023 (KR) 10-2023-0181899

(51) Int. Cl. H10K 59/80; H10K 59/12; H10K 59/122

(52) U.S. Cl. CPC H10K 59/80516; H10K 59/1201; H10K 59/122

(57) ABSTRACT

A display device includes: a metal layer on a via layer, the metal layer overlapping with emission areas; a resonance auxiliary layer on the via layer and the metal layer, the resonance auxiliary layer exposing the metal layer; anode electrodes on the resonance auxiliary layer; and a contact layer connected to the metal layer and the anode electrodes.

### CROSS-REFERENCE TO RELATED APPLICATION

The present application claims priority to and the benefit of Korean Patent Application No. 10-2023-0181899, filed on Dec. 14, 2023, in the Korean Intellectual Property Office, the entire disclosure of which is incorporated herein by reference.

### BACKGROUND

### 1. Field

Aspects of some embodiments of the present disclosure relate to a display device and a method of manufacturing the display device.

### 2. Description of Related Art

With the development of information technology, the importance of display devices, which provide a connection medium between users and information, has been emphasized. Accordingly, display devices such as liquid crystal display devices and organic light emitting display devices are increasingly used.

The above information disclosed in this Background section is only for enhancement of understanding of the background and therefore the information discussed in this Background section does not necessarily constitute prior art.

### SUMMARY

Aspects of some embodiments of the present disclosure include a display device and a method of manufacturing the display device, in which anode electrodes can be patterned without any etching process, and electrical characteristics can be relatively improved.

According to some embodiments of the present disclosure, a display device includes: a metal layer on a via layer, the metal layer overlapping with emission areas, a resonance auxiliary layer on the via layer and the metal layer, the resonance auxiliary layer exposing the metal layer, anode electrodes on the resonance auxiliary layer, and a contact layer connected to the metal layer and the anode electrodes.

According to some embodiments, the metal layer may include: a first metal layer connected to a via of the via layer, a second metal layer on the first metal layer, and a third metal layer on the second metal layer.

According to some embodiments, an electrical conductivity of the second metal layer may be higher than an electrical conductivity of the third metal layer.

According to some embodiments, the contact layer may be connected to the second metal layer while penetrating the third metal layer.

According to some embodiments, the display device may further include a pixel defining layer on the resonance auxiliary layer, the anode electrodes, and the contact layer, the pixel defining layer exposing the anode electrodes.

According to some embodiments, the display device may further include a protective layer on the anode electrodes and the contact layer, the protective layer exposing the anode electrodes.

According to some embodiments, the display device may further include a pixel defining layer on the resonance auxiliary layer, the anode electrodes, and the protective layer, the pixel defining layer having an undercut structure.

According to some embodiments, the resonance auxiliary layer may include an inorganic material.

According to some embodiments, the contact layer may include a metal material.

According to some embodiments of the present disclosure, a method of manufacturing a display device includes: forming a metal layer on a via layer, forming a resonance auxiliary layer exposing the metal layer on the via layer and the metal layer, forming a first photosensitive pattern on the resonance auxiliary layer and the exposed metal layer, forming anode electrodes on the resonance auxiliary layer and the first photosensitive pattern, stripping the first photosensitive pattern, and forming a contact layer penetrating the metal layer.

According to some embodiments, the forming of the metal layer may include: forming a first metal layer connected to a via of the via layer, forming a second metal layer on the first metal layer, and forming a third metal layer on the second metal layer.

According to some embodiments, an electrical conductivity of the second metal layer may be higher than an electrical conductivity of the third metal layer.

According to some embodiments, the first photosensitive pattern may be formed in a reverse tapered shape.

According to some embodiments, the forming of the contact layer may include: forming a second photosensitive pattern on the resonance auxiliary layer and the anode electrodes, etching the third metal layer such that the second metal layer is exposed, stripping the second photosensitive pattern, and forming the contact layer to be connected to the anode electrodes on the exposed second metal layer.

According to some embodiments, the method may further include forming a pixel defining layer exposing the anode electrodes on the resonance auxiliary layer, the anode electrodes, and the contact layer.

According to some embodiments, the method may further include forming a protective layer on the contact layer and the anode electrodes.

According to some embodiments, the method may further include forming a pixel defining layer exposing the protective layer on the resonance auxiliary layer, the anode electrodes, and the protective layer.

According to some embodiments, the method may further include etching the protective layer such that the pixel defining layer has an undercut structure.

According to some embodiments, the resonance auxiliary layer may include an inorganic material.

According to some embodiments, the contact layer may include a metal material.

### BRIEF DESCRIPTION OF THE DRAWINGS

The above and other aspects and features of embodiments according to the present disclosure will become more apparent by describing, in further detail, aspects of some embodiments thereof with reference to the accompanying drawings, in which:

FIG. 1 is a block diagram schematically illustrating a display device according to some embodiments of the present disclosure.

FIG. 2 is a block diagram schematically illustrating a sub-pixel according to some embodiments of the present disclosure.

FIG. 3 is a plan view illustrating aspects of a display panel shown in FIG. 1 according to some embodiments of the present disclosure.

FIG. 4 is an exploded perspective view illustrating aspects of a portion of the display panel shown in FIG. 3 according to some embodiments of the present disclosure.

FIG. 5 is a sectional view schematically illustrating a light emitting structure according to some embodiments of the present disclosure.

FIG. 6 is a sectional view schematically illustrating a light emitting structure according to some embodiments of the present disclosure.

FIG. 7 is a plan view illustrating aspects of a pixel shown in FIG. 4 according to some embodiments of the present disclosure.

FIG. 8 is a plan view illustrating aspects of a pixel shown in FIG. 4 according to some embodiments of the present disclosure.

FIG. 9 is a plan view illustrating aspects of a pixel shown in FIG. 4 according to some embodiments of the present disclosure.

FIG. 10 is a sectional view taken along the line I-I′ shown in FIG. 7 according to some embodiments of the present disclosure.

FIG. 11 is a sectional view taken along the line I-I′ shown in FIG. 7 according to some embodiments of the present disclosure.

FIG. 12 is a flowchart illustrating a manufacturing method of the display device according to some embodiments of the present disclosure.

FIGS. 13 to 20 are sectional views schematically illustrating aspects of the manufacturing method shown in FIG. 12 according to some embodiments of the present disclosure.

FIG. 21 is a flowchart illustrating a manufacturing method of the display device according to some embodiments of the present disclosure.

FIGS. 22 to 24 are sectional views schematically illustrating aspects of operations S800 to S1000 in the manufacturing method shown in FIG. 21 according to some embodiments of the present disclosure.

FIG. 25 is a block diagram illustrating a display system according to some embodiments of the present disclosure.

FIG. 26 is a perspective view illustrating an application example of the display system shown in FIG. 25 according to some embodiments of the present disclosure.

FIG. 27 is a view illustrating a head-mounted display device shown in FIG. 26, which is worn by a user according to some embodiments of the present disclosure.

### DETAILED DESCRIPTION

Hereinafter, embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to the disclosed embodiments described herein, but may be embodied in various different forms. Rather, the disclosed embodiments described herein are provided to more thoroughly and more completely describe aspects of some embodiments of the present disclosure to more sufficiently convey the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating aspects of some embodiments and not intended to limit the embodiments. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items of X, Y, and Z (e.g., XYZ, XY, YZ, ZZ). Similarly, for the purposes of this disclosure, “at least one selected from the group consisting of X, Y, and Z” can be construed as X only, Y only, Z only, or any combination of two or more items of X, Y, and Z (e.g., XYZ, XY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

Hereinafter, embodiments of the present disclosure will be described in more detail with reference to the accompanying drawings.

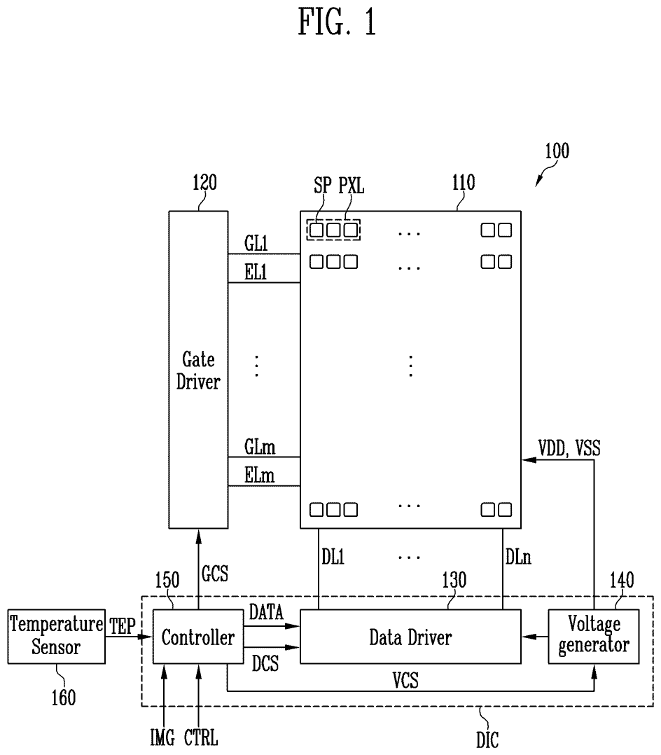

FIG. 1 is a block diagram schematically illustrating a display device according to some embodiments of the present disclosure.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm. The sub-pixels SP may be connected to the data driver 130 through first to nth data lines DL1 to DLn. The number of rows and columns of sub-pixels SP, and therefor the number of gate lines and data lines, may vary according to the design and size of the display device 100.

Each of the sub-pixels SP may include at least one light emitting element configured to generate light. Accordingly, each of the sub-pixels SP may generate light of a specific color such as red, green, blue, cyan, magenta, and/or yellow. Two or more sub-pixels among the sub-pixels SP may constitute one pixel PXL. For example, three sub-pixels SP may constitute one pixel PXL as shown in FIG. 1, but embodiments according to the present disclosure are not limited thereto, and according to some embodiments, the display device 100 may be designed such that four or more sub-pixels SP may constitute one pixel PXL.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. According to some embodiments, the gate control signal GCS may include a start signal indicating a start of each frame, a horizontal synchronization signal for outputting gate signals in synchronization with timings at which data signals are applied, and the like.

According to some embodiments, first to mth emission control lines EL1 to ELm connected to the sub-pixels SP in the row direction may be further provided. The gate driver 120 may include an emission control driver configured to control the first to mth emission control lines EL1 to ELm, and the emission control driver may operate under the control of the controller 150.

The gate driver 120 may be located at one side of the display panel 110. However, embodiments according to the present disclosure are not limited thereto. For example, the gate driver 120 may be divided into two or more drivers which are physically and/or logically divided, and these drivers may be located at a first side of the display panel 110 and a second side of the display panel 110, which is opposite to the first side. Additionally, according to some embodiments, the gate driver 120 may be divided into two or more drivers that are located on adjacent sides or more than two sides of the display panel 110. As such, in some embodiments, the gate driver 120 may be located in various forms at the periphery of the display panel 110.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. According to some embodiments, the data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the first to nth data line DL1 to DLn. Accordingly, corresponding sub-pixels SP may generate light corresponding to the data signals. Accordingly, images may be displayed on the display panel 110.

According to some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. According to some embodiments, the first power voltage VDD or the second power voltage VSS may be provided by an external device of the display device 100.

Besides, the voltage generator 140 may generate various voltages. For example, the voltage generator 140 may generate an initialization voltage applied to the sub-pixels SP. For example, a reference voltage (e.g., a set or predetermined reference voltage) may be applied to the first to nth data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. According to some embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. According to some embodiments, at least one of the data driver 130, the voltage generator 140, and the controller 150 may be provided as a component distinguished from the driver integrated circuit DIC.

The display device 100 may include at least one temperature sensor 160. The temperature sensor 160 may be configured to sense a temperature at the periphery thereof and generate temperature data TEP indicating the sensed temperature. According to some embodiments, the temperature sensor 160 may be adjacent to the display panel 110 and/or the driver integrated circuit DIC.

The controller 150 may control various operations of the display device 100 in response to the temperature data TEP. According to some embodiments, the controller 150 may adjust the luminance of an image output from the display device 100 in response to the temperature data TEP. For example, the controller 150 may control components such as the data driver 130 and/or the voltage generator 140, thereby adjusting data signals and the first and second power voltages VDD and VSS.

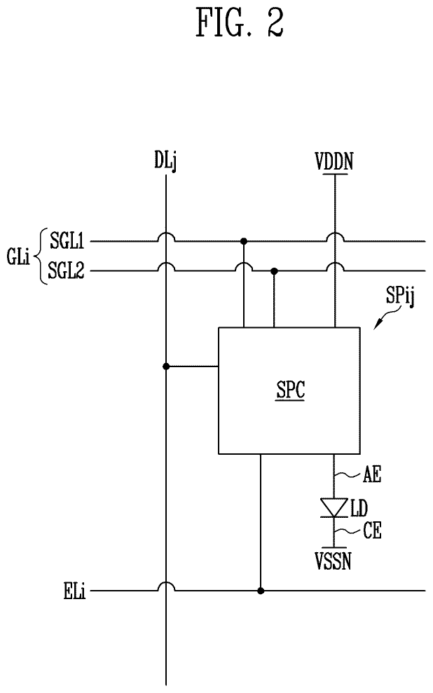

FIG. 2 is a block diagram schematically illustrating a sub-pixel according to some embodiments of the present disclosure. In FIG. 2, a sub-pixel SPij arranged on an ith row (i is an integer which is greater than or equal to 1 and is smaller than or equal to m) and a jth column (j is an integer which is greater than or equal to 1 and is smaller than or equal to n) among the sub-pixels SP shown in FIG. 1 is illustrated as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an ith gate line GLi among the first to mth gate lines GL1 to GLm shown in FIG. 1, an ith emission control line ELi among the first to mth emission control lines EL1 to ELm shown in FIG. 1, and a jth data line DLj among the first to nth data lines DL1 to DLn shown in FIG. 1. The sub-pixel circuit SPC may be configured to control the light emitting element LD according to signals received through these signal lines.

The sub-pixel circuit SPC may operate in response to a gate signal received through the ith gate line GLi. The ith gate line GLi may include one or more sub-gate lines. According to some embodiments, as shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. According to some embodiments, the ith emission control line ELi may include one or more sub-emission control lines. When the ith emission control line ELi includes two or more sub-emission control lines, the sub-pixel circuit SPC may operate in response to emission control signals receives through the corresponding emission control lines.

The sub-pixel circuit SPC may receive a data signal through the jth data line DLj. The sub-pixel circuit SPC may store a voltage corresponding to the data signal in response to at least one of the gate signals received through the first or second sub-gate lines SGL1 or SGL2. The sub-pixel circuit SPC may control a current flowing from the first power voltage node VDDN to the second power voltage node VSSN through the light emitting element LD according to the stored voltage in response to the emission control signal received through the ith emission control line ELi. Accordingly, the light emitting element LD may generate light with a luminance corresponding to the data signal.

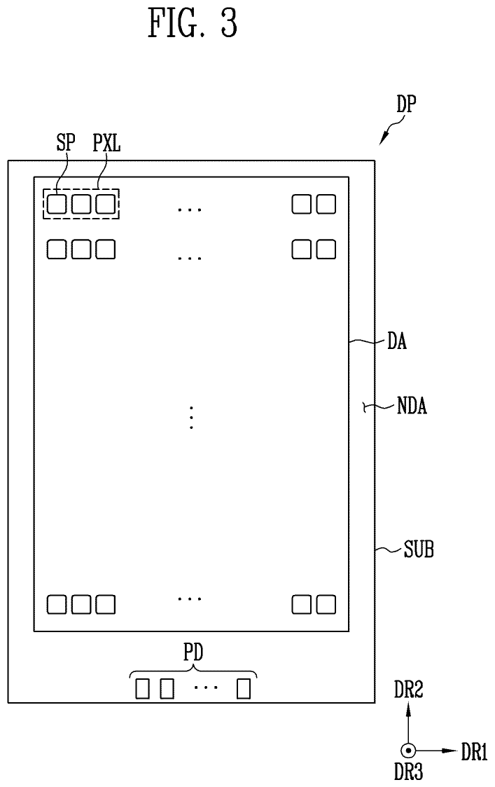

FIG. 3 is a plan view illustrating aspects of the display panel shown in FIG. 1 according to some embodiments of the present disclosure.

Referring to FIG. 3, the display panel DP (i.e., the display panel 110 shown in FIG. 1) may include a display area DA and a non-display area NDA. The display panel DP may display images at or through the display area DA. The non-display area NDA may be located at the periphery (or outside a footprint) of the display area DA.

The display panel DP may include a substrate SUB, sub-pixels SP, and pads PD.

When the display panel DP is used as a display screen of a Head Mounted Display (HMD), a Virtual Reality (VR) device, a Mixed Reality (MR) device, an Augmented Reality (AR) device, and the like, the display panel DP may be located very close to eyes of a user. The sub-pixels SP having a relatively high degree of integration may be required. In order to increase the integration of the sub-pixels SP, the substrate SUB may be provided as a silicon substrate. The sub-pixels SP and/or the display panel DP may be formed on the substrate SUB as the silicon substrate. The display device 100 (see FIG. 1) including the display panel DP formed on the substrate SUB as the silicon substrate may be designated as an OLED on Silicon (OLEDoS) display device.

The sub-pixels SP may be located in the display area DA on the substrate SUB. The sub-pixels SP may be arranged in a matrix form along a first direction DR1 and a second direction DR2 intersecting the first direction DR1. However, embodiments according to the present disclosure are not limited thereto. For example, the sub-pixels SP may be arranged in a zigzag form along the first direction DR1 and the second direction DR2. For example, the sub-pixels SP may be arranged in a PENTILE™ form or arrangement. The first direction DR1 may be a row direction, and the second direction DR2 may be a column direction.

Two or more sub-pixels among the sub-pixels SP may constitute one pixel PXL.

A component for controlling the sub-pixels SP may be located in the non-display area NDA on the substrate SUB. For example, lines connected to the sub-pixels SP, such as the first to mth gate lines GL1 to GLm and the first to nth data lines DL1 to DLn, which are shown in FIG. 1, may be located in the non-display area NDA.

At least one of the gate driver 120, the data driver 130, the voltage generator 140, the controller 150, and the temperature sensor 160, which are shown in FIG. 1, may be integrated in the non-display area NDA of the display panel DP. According to some embodiments, the gate driver 120 shown in FIG. 1 is mounted on the display panel DP, and may be located in the non-display area NDA. According to some embodiments, the gate driver 120 may be implemented as an integrated circuit distinguished from the display panel DP. According to some embodiments, the temperature sensor 160 may be located in the non-display area NDA to sense a temperature of the display panel DP.

The pads PD may be located in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel DP with other components of the display device 100 (see FIG. 1). According to some embodiments, voltages and signals, which may be utilized for operations of components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

According to some embodiments, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

According to some embodiments, the display area DA may have various shapes. The display area DA may have a closed-loop shape including linear sides and/or curved sides. For example, the display area DA may have shapes such as a polygon, a circle, a semicircle, and an ellipse.

According to some embodiments, the display panel DP may have a flat display surface. According to some embodiments, the display panel DP may at least partially have a round display surface. According to some embodiments, the display panel DP may be bendable, foldable, or rollable, without damaging the display device 100. The display panel DP and/or the substrate SUB may include materials having flexibility.

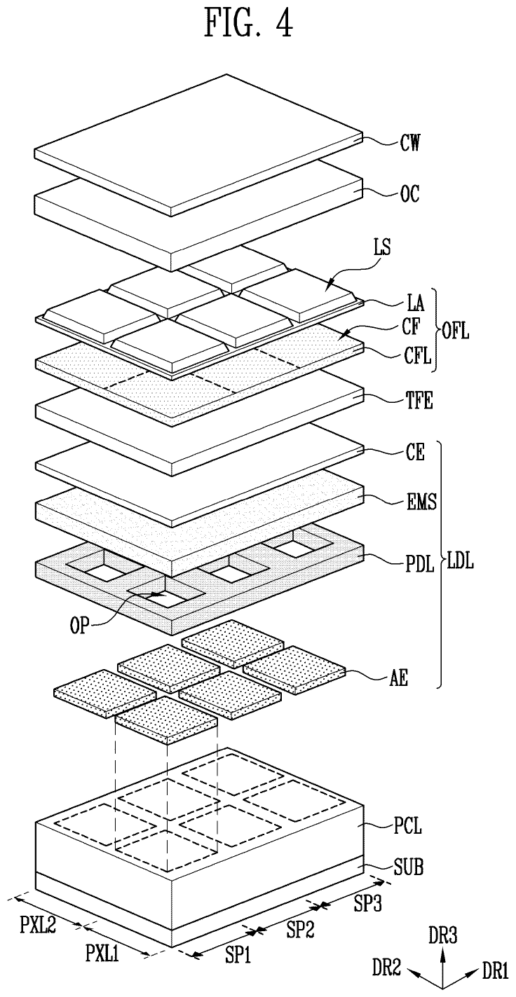

FIG. 4 is an exploded perspective view illustrating a portion of the display panel shown in FIG. 3 according to some embodiments of the present disclosure. In FIG. 4, for clear and brief description, a portion of the display panel DP, which corresponds to two pixels PXL1 and PXL2 among the pixels PXL shown in FIG. 3, is schematically illustrated. A portion of the display panel DP, which corresponds to the other pixels, may also be configured identically.

Referring to FIGS. 3 and 4, each of first and second pixels PXL1 and PXL2 may include first to third sub-pixels SP1, SP2, and SP3. However, embodiments according to the present disclosure are not limited thereto. For example, each of the first and second pixels PXL1 and PXL2 may include four sub-pixels or include two sub-pixels.

In FIG. 4, it may be illustrated that the first to third sub-pixels SP1 to SP3 may have quadrangular shapes when viewed in a third direction DR3 (e.g., in a plan view) intersecting the first and second directions DR1 and DR2, and have the same size. However, embodiments according to the present disclosure are not limited thereto. The first to third sub-pixels SP1 to SP3 may be modified to have various shapes.

The display panel DP may include a substrate SUB, a pixel circuit layer PCL, a light emitting element layer LDL, an encapsulation layer TFE, an optical functional layer OFL, an overcoat layer OC, and a cover window CW.

According to some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. According to some embodiments, the substrate SUB may include a glass substrate. According to some embodiments, the substrate SUB may include a polyimide (PI) substrate.

The pixel circuit layer PCL may be located on the substrate SUB. The substrate SUB and/or the pixel circuit layer PCL may include insulating layers and conductive patterns located between the insulating layers. The conductive patterns of the pixel circuit layer PCL may serve as at least some of circuit elements, lines, and the like. The conductive patterns may include copper, but embodiments according to the present disclosure are not limited thereto.

The circuit elements may include a sub-pixel circuit SPC (see FIG. 2) of each of the first to third sub-pixels SP1, SP2, and SP3. The sub-pixel circuit SPC may include transistors and one or more capacitors. Each transistor may include a semiconductor portion including a source region, a drain region, and a channel region, and a gate electrode overlapping with the semiconductor portion. According to some embodiments, when the substrate SUB is provided as a silicon substrate, the semiconductor portion may be included in the substrate SUB, and the gate electrode may be included as a conductive pattern of the pixel circuit layer PCL in the pixel circuit layer PCL. According to some embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, the capacitor may include electrodes spaced apart from each other in the third direction DR3 with an insulating layer interposed therebetween.

The lines of the pixel circuit layer PCL may include signal lines, e.g., a gate line, an emission control line, a data line, and the like, which are connected to each of the first to third sub-pixels SP1, SP2, and SP3. The lines may further include a line connected to the first power voltage node VDDN shown in FIG. 2. The lines may further include a line connected to the second power voltage node VSSN shown in FIG. 2.

The light emitting element layer LDL may include anode electrodes AE, a pixel defining layer PDL, a light emitting structure EMS, and a cathode electrode CE.

The anode electrodes AE may be located on the pixel circuit layer PCL. The anode electrodes AE may be electrically connected to circuit elements of the pixel circuit layer PCL. The anode electrodes AE may include an opaque conductive material capable of reflecting light, but embodiments are not limited thereto.

The pixel defining layer PDL may be arranged over the anode electrodes AE. The pixel defining layer PDL may include an opening OP exposing a portion of each of the anode electrodes AE. The opening OP of the pixel defining layer PDL may be understood as an emission area corresponding to each of the first to third sub-pixels SP1 to SP3.

According to some embodiments, the pixel defining layer PDL may include an inorganic material. The pixel defining layer PDL may include a plurality of stacked inorganic layers. For example, the pixel defining layer PDL may include silicon oxide (SiOₓ) and silicon nitride (SiNₓ). According to some embodiments, the pixel defining layer PDL may include an organic material. However, the material of the pixel defining layer PDL is not limited thereto.

The light emitting structure EMS may be located on the anode electrodes AE exposed by the openings OP of the pixel defining layer PDL. The light emitting structure EMS may include a light generation layer configured to generate light, an electron transport layer configured to transport electrons, a hole transport layer configured to transport holes, and the like.

According to some embodiments, the light emitting structure EMS fills the openings OP of the pixel defining layer PDL, and may be entirely located on the top of the pixel defining layer PDL. The light emitting structure EMS may extend throughout the first to third sub-pixels SP1 to SP3. At least some of the layers in the light emitting structure EMS may be separated (cut) or bent at boundaries between the first to third sub-pixels SP1 to SP3. However, embodiments according to the present disclosure are not limited thereto. For example, portions of the light emitting structure EMS, which correspond to the first to third sub-pixels SP1 to SP3, may be separated from each other, and each of the separated portions of the light emitting structure EMS may be located in the opening OP of the pixel defining layer PDL.

The cathode electrode CE may be located on the light emitting structure EMS. The cathode electrode CE may extend throughout the first to third sub-pixels SP1 to SP3. As such, the cathode electrode CE may be provided as a common electrode for the first to third sub-pixels SP1 to SP3.

The cathode electrode CE may be a thin metal layer having a thickness to a degree to which light emitted from the light emitting structure EMS can be transmitted therethrough. The cathode electrode CE may be formed of a metal material to have a relatively thin thickness or be formed of a transparent conductive material. According to some embodiments, the cathode electrode CE may include at least one of various transparent conductive materials including indium tin oxide, indium zinc oxide, indium tin zinc oxide, aluminum zinc oxide, gallium zinc oxide, zinc tin oxide, and gallium tin oxide. According to some embodiments, the cathode electrode CE may include at least one of silver (Ag), magnesium (Mg), and mixtures thereof. However, the material of the cathode electrode CE is not limited thereto.

It may be understood that any one of the anode electrodes AE, a portion of the light emitting structure EMS, which overlaps therewith, and a portion of the cathode electrode CE, which overlaps therewith, constitute one light emitting element LD (see FIG. 2). Each of light emitting elements LD of the first to third sub-pixels SP1 to SP3 may include one anode electrode AE, a portion of the light emitting structure EMS, which overlaps therewith, and a portion of the cathode electrode CE, which overlaps therewith. In each of the first to third sub-pixels SP1 to SP3, holes injected from the anode electrode AE and electrons injected from the cathode electrode CE may be transported into a light emitting layer of the light emitting structure EMS to form excitons, and light may be generated when the excitons are changed from an excited state to a ground state. A luminance of the light may be determined according to an amount of current flowing through the light emitting layer. A wavelength band of the generated light may be determined according to a configuration of the light emitting layer.

The encapsulation layer TFE may be arranged over the cathode electrode CE. The encapsulation layer TFE may cover the light emitting element layer LDL and/or the pixel circuit layer PCL. The encapsulation layer TFE may be configured to prevent oxygen and/or moisture from infiltrating into the light emitting element layer LDL. According to some embodiments, the encapsulation layer TFE may include a structure in which at least one inorganic layer and at least one organic layer are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

In order to relatively improve encapsulation efficiency of the encapsulation layer TFE, the encapsulation layer TFE may further include a thin film including aluminum oxide (AlOₓ). The thin film including the aluminum oxide may be located on a top surface of the encapsulation layer TFE, which faces the optical functional layer OFL, and/or a bottom surface of the encapsulation layer TFE, which faces the light emitting element layer LDL.

The thin film including the aluminum oxide may be formed through an Atomic Layer Deposition (ALD) process. However, embodiments according to the present disclosure are not limited thereto. The encapsulation layer TFE may further include a thin film formed of at least one of various materials suitable for the improvement of the encapsulation efficiency.

The optical functional layer OFL may be located on the encapsulation layer TFE. The optical functional layer OFL may include a color filter layer CFL and a lens array LA.

The color filter layer CFL may be located between the encapsulation layer TFE and the lens array LA. The color filter layer CFL may be configured filter light emitted from the light emitting structure EMS, thereby selectively outputting light of a wavelength band or a color, which corresponds to each sub-pixel. The color filter layer CFL may include color filters CF respectively corresponding to the first to third sub-pixels SP1 to SP3. Each of the color filters CF may allow light having a wavelength band corresponding to a corresponding sub-pixel to pass therethrough. For example, a color filter CF corresponding to the first sub-pixel SP1 may allow light of a red color to pass therethrough, a color filter CF corresponding to the second sub-pixel SP2 may allow light of a green color to pass therethrough, and a color filter CF corresponding to the third sub-pixel SP3 may allow light of a blue color to pass therethrough. According to light emitted from the light emitting structure EMS in each sub-pixel, at least some of the color filters CF may be omitted.

The lens array LA may be located on the color filter layer CFL. The lens array LA may include lenses LS respectively corresponding to the first to third sub-pixels SP1 to SP3. Each of the lenses LS may output light emitted from the light emitting structure EMS along an intended path, thereby improving light emission efficiency. The lens array LA may have a relatively high refractive index. For example, the lens array LA may have a refractive index higher than a refractive index of the overcoat layer OC. According to some embodiments, the lenses LS may include an organic material. According to some embodiments, the lenses LS may include an acryl-based material. However, the material of the lenses LS is not limited thereto.

According to some embodiments, as compared with the opening OP of the pixel defining layer PDL, at least some of the color filters CF of the color filter layer CFL and at least some of the lenses LS of the lens array LA may be shifted in a direction parallel to a plane defined by the first and second directions DR1 and DR2. For example, in a central area of the display area DA, the center of the color filter CF and the center of the lens LS may be aligned or overlap with the center of a corresponding opening OP of the pixel defining layer PDL when viewed in the third direction DR3 (e.g., in a plan view). For example, in the central area of the display area DA, the opening OP of the pixel defining layer PDL may completely overlap with a corresponding color filter CF of the color filter layer CFL and a corresponding lens LS of the lens array LA.

In an area adjacent to the non-display area NDA of the display area DA, the center of the color filter CF and the center of the lens LS may be shifted in a plane direction from the center of the opening OP of the pixel defining layer PDL when viewed in the third direction DR3 (e.g., in a plan view). For example, in an area adjacent to the non-display area NDA of the display area DA, the opening OP of the pixel defining layer PDL may partially overlap with a corresponding color filter CF of the color filter layer CFL and a corresponding lens LS of the lens array LA. Accordingly, at the center of the display area DA, light emitted from the light emitting structure EMS can be efficiently output in a normal direction of the display surface. At an outer portion of the display area DA, light emitted from the light emitting structure EMS can be efficiently output in a direction inclined by an angle (e.g., a set or predetermined angle) with respect to the normal direction.

The overcoat layer OC may be arranged over the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign matters such as dust and moisture. For example, the overcoat layer OC may include at least one of an inorganic insulating layer and an organic insulating layer. For example, the overcoat layer OC may include epoxy, but embodiments according to the present disclosure are not limited thereto. The overcoat layer OC may have a refractive index lower than a refractive index of the lens array LA.

The cover window CW may be located on the overcoat layer OC. The cover window CW may be configured to protect lower layers thereof. The cover window CW may have a refractive index higher than the refractive index of the overcoat layer OC. The cover window CW may include glass, but embodiments according to the present disclosure are not limited thereto. For example, the cover window CW may be an encapsulation glass configured to protect components located on the bottom thereof. According to some embodiments, the cover window CW may be omitted.

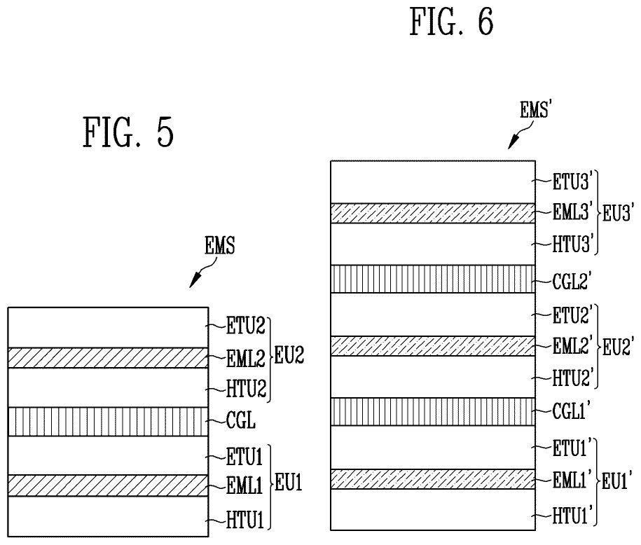

FIG. 5 is a sectional view schematically illustrating a light emitting structure according to some embodiments of the present disclosure.

Referring to FIG. 5, the light emitting structure EMS may have a tandem structure in which first and second light emitting units EU1 and EU2 are stacked.

Each of the first and second light emitting units EU1 and EU2 may include at least one light emitting layer generating light according to an applied current. The first light emitting unit EU1 may include a first light emitting layer EML1, a first electron transport unit ETU1, and a first hole transport unit HTU1. The first light emitting layer EML1 may be located between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be located between the second electron transport unit ETU2 and the second hole transport unit HTU2.

Each of the first and second hole transport units HTU1 and HTU2 may include at least one of a hole injection layer and a hole transport layer. Each of the first and second hole transport units HTU1 and HTU2 may further include a hole buffer layer, an electron blocking layer, and the like, if necessary. The first and second hole transport units HTU1 and HTU2 may have the same configuration or have different configurations.

Each of the first and second electron transport units ETU1 and ETU2 may include at least one of an electron injection layer and an electron transport layer. Each of the first and second electron transport units ETU1 and ETU2 may further include an electron buffer layer, a hole blocking layer, and the like, if necessary. The first and second electron transport units ETU1 and ETU2 may have the same configuration or have different configurations.

A connection layer, which may be provided in the form of a charge generation layer CGL, may be located between the first light emitting unit EU1 and the second light emitting unit EU2 to connect the first light emitting unit EU1 and the second light emitting unit EU2 to each other. According to some embodiments, the charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or any combination thereof. However, embodiments according to the present disclosure are not limited thereto.

According to some embodiments, the first light emitting layer EML1 and the second light emitting layer EML2 may generate lights of different colors. Lights respectively emitted from the first light emitting layer EML1 and the second light emitting layer EML2 may be mixed together, to be viewed as white light. For example, the first light emitting layer EML1 may generate light of a blue color, and the second light emitting layer EML2 may generate light of a yellow color. According to some embodiments, the second light emitting layer EML2 may include a structure in which a first sub-light emitting layer configured to generate light of a red color and a second sub-light emitting layer configured to generate light of a green color are stacked. The light of the red color and the light of the green color may be mixed together to provide the light of the yellow color. An intermediate layer configured to perform a function of transporting holes and/or a function of blocking transportation of electrons may be further located between the first and second sub-light emitting layers.

According to some embodiments, the first light emitting layer EML1 and the second light emitting layer EML2 may generate light of the same color.

The light emitting structure EMS may be formed through a process such as vacuum deposition or inkjet printing, but embodiments according to the present disclosure are not limited thereto.

Unlike as shown in FIG. 5, the light emitting structure EMS may include one light emitting unit. Light emitting units included in the respective first to third sub-pixels SP1 to SP3 (see FIG. 4) may be configured to emit lights of different colors. For example, the light emitting unit of the first sub-pixel SP1 may emit light of a red color, the light emitting unit of the second sub-pixel SP2 may emit light of a green color, and the light emitting unit of the third sub-pixel SP3 may emit light of a blue color. The light emitting units of the first to third sub-pixels SP1 to SP3 may be separated from each other, and each of the separated light emitting units may be located in the opening OP of the pixel defining layer PDL. At least some of the color filters shown in FIG. 4 may be omitted.

FIG. 6 is a sectional view schematically illustrating a light emitting structure according to some embodiments of the present disclosure.

Referring to FIG. 6, a light emitting structure EMS' may a tandem structure in which first to third light emitting units EU1′ to EU3′ are stacked.

Each of the first to third light emitting units EU1′ to EU3′ may include a light emitting layer generating light according to an applied current. The first light emitting unit EU1′ may include a first light emitting layer EML1′, a first electron transport unit ETU1′ and a first hole transport unit HTU1′. The first light emitting layer EML1′ may be located between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be located between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be located between the third electron transport unit ETU3′ and the third hole transport unit HTU3′.

Each of the first to third hole transport units HTU1′ to HTU3′ may include at least one of a hole injection layer and a hole transport layer, and further include a hole buffer layer, and/or an electron blocking layer, and the like, according to some embodiments. The first to third hole transport units HTU1′ to HTU3′ may have the same configuration or have different configurations.

Each of the first to third electron transport units ETU1′ to ETU3′ may include at least one of an electron injection layer and an electron transport layer, and further include an electron buffer layer, a hole blocking layer, and the like, according to some embodiments. The first to third electron transport units ETU1′ to ETU3′ may have the same configuration or have different configurations.

A first charge generation layer CGL1′ may be located between the first light emitting unit EU1′ and the second light emitting unit EU2′. A second charge generation layer CGL2′ may be located between the second light emitting unit EU2′ and the third light emitting unit EU3′.

According to some embodiments, the first to third light emitting layers EML1′ to EML3′ may generate lights of different colors. Lights respectively emitted from the first to third light emitting layers EML1′ to EML3′ may be mixed together, to be viewed as white light. For example, the first light emitting layer EML1′ may generate light of a blue color, the second light emitting layer EML2′ may generate light of a green color, and the third light emitting layer EML3′ may generate light of a red color.

According to some embodiments, at least two of the first to third light emitting layers EML1′ to EML3′ may generate light of the same color.

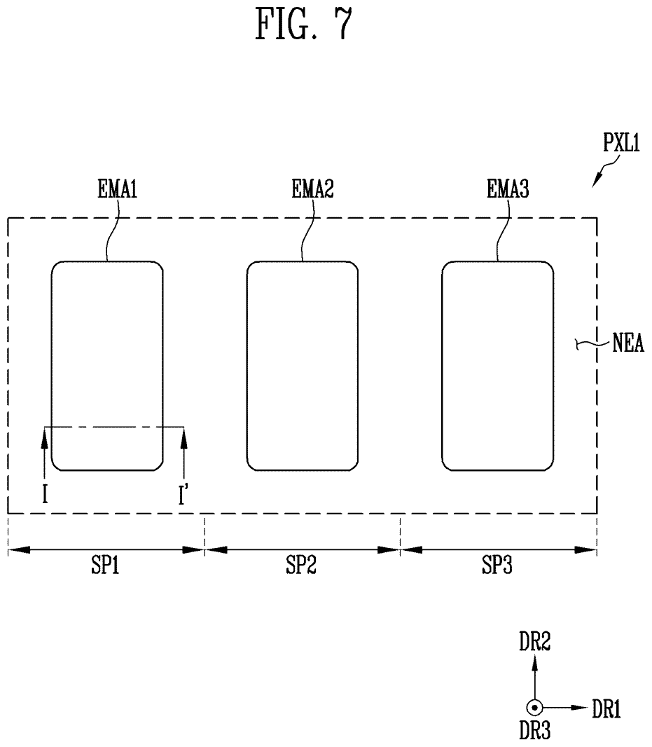

FIG. 7 is a plan view illustrating aspects of a pixel shown in FIG. 4 according to some embodiments of the present disclosure. In FIG. 7, for clear and brief description, the first pixel PXL1 among the first and second pixels PXL1 and PXL2 shown in FIG. 4 is schematically illustrated. The other pixels may be configured identically to the first pixel PXL1.

Referring to FIGS. 4 and 7, the first pixel PXL1 may include first to third sub-pixels SP1 to SP3 arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

The first emission area EMA1 may be an area in which light is emitted from a portion of the light emitting structure EMS (see FIG. 4), which corresponds to the first sub-pixel SP1. The second emission area EMA2 may be an area in which light is emitted from a portion of the light emitting structure EMS, which corresponds to the second sub-pixel SP2. The third emission area EMA3 may be an area in which light is emitted from a portion of the light emitting structure EMS, which corresponds to the third sub-pixel SP3. As described with reference to FIG. 4, each emission area may be understood as the opening OP of the pixel defining layer PDL, which corresponds to each of the first to third sub-pixels SP1 to SP3.

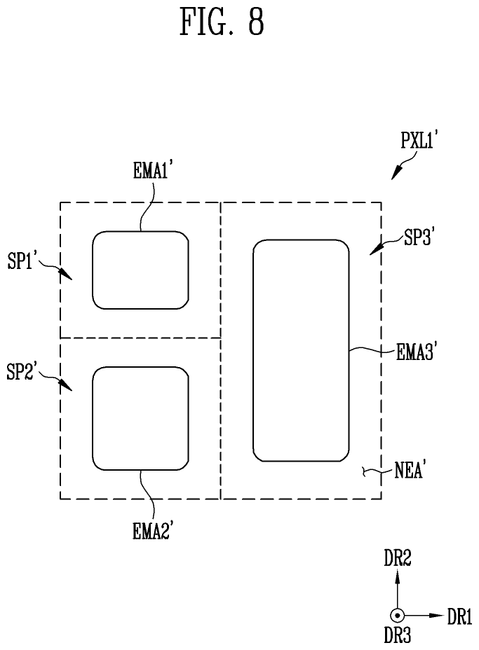

FIG. 8 is a plan view illustrating aspects of a pixel shown in FIG. 4 according to some embodiments of the present disclosure.

Referring to FIG. 8, a first pixel PXL1′ may include first to third sub-pixels SP1′ to SP3′.

The first sub-pixel SP1′ may include a first emission area EMA1′ and a non-emission area NEA′ at the periphery of the first emission area EMA1′. The second sub-pixel SP2′ may include a second emission area EMA2′ and the non-emission area NEA′ at the periphery of the second emission area EMA2′. The third sub-pixel SP3′ may include a third emission area EMA3′ and the non-emission area NEA′ at the periphery of the third emission area EMA3′.

The first sub-pixel SP1′ and the second sub-pixel SP2′ may be arranged in the second direction DR2. The third sub-pixel SP3′ may be located in the first direction DR1 with respect to each of the first and second sub-pixels SP1′ and SP2′.

The second sub-pixel SP2′ may have an area greater than an area of the first sub-pixel SP1′, and the third sub-pixel SP3′ may have an area greater than the area of the second sub-pixel SP2′. Accordingly, the second emission area EMA2′ may have an area greater than an area of the first emission area EMA1′, and the third emission area EMA3′ may have an area greater than the area of the second emission area EMA2′. However, embodiments according to the present disclosure are not limited thereto. For example, the first and second sub-pixels SP1′ and SP2′ may substantially have the same area, and the third sub-pixel SP3′ may have an area greater than the area of each of the first and second sub-pixels SP1′ and SP2′. As such, the areas of the first to third sub-pixels SP1′ to SP3′ may be variously modified in some embodiments.

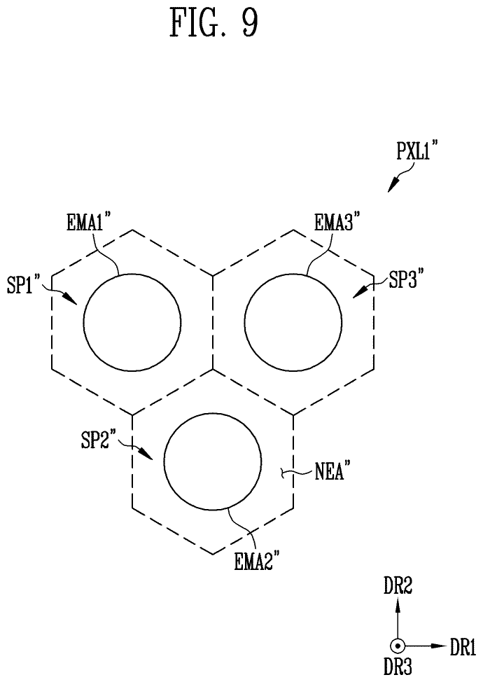

FIG. 9 is a plan view illustrating aspects of a pixel shown in FIG. 4 according to some embodiments of the present disclosure.

Referring to FIG. 9, a first pixel PXL1″ may include first to third sub-pixels SP1″ to SP3″.

The first sub-pixel SP1″ may include a first emission area EMA1″ and a non-emission area NEA″ at the periphery of the first emission area EMA1″. The second sub-pixel SP2″ may include a second emission area EMA2″ and the non-emission area NEA″ at the periphery of the second emission area EMA2″. The third sub-pixel SP3″ may include a third emission area EMA3″ and the non-emission area NEA″ at the periphery of the third emission area EMA3″.

The first to third sub-pixels SP1″ to SP3″ may have polygonal shapes when viewed in the third direction DR3 (e.g., in a plan view). For example, the shapes of the first to third sub-pixels SP1″ to SP3″ may be hexagonal shapes as shown in FIG. 9.

The first to third emission areas EMA1″ to EMA3″ may have circular shapes when viewed in the third direction DR3 (e.g., in a plan view). However, embodiments according to the present disclosure are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be arranged in a direction (or diagonal direction) inclined by an acute angle, based on the second direction DR2, with respect to the first sub-pixel SP1″.

The arrangements of the sub-pixels, which are shown in FIGS. 7, 8, and 9, are merely illustrative, and embodiments according to the present disclosure are not limited thereto. Each pixel may include two or more sub-pixels, and the sub-pixels may be arranged in various manners. Each of the sub-pixels may have various shapes, and an emission area of the sub-pixel may have various shapes.

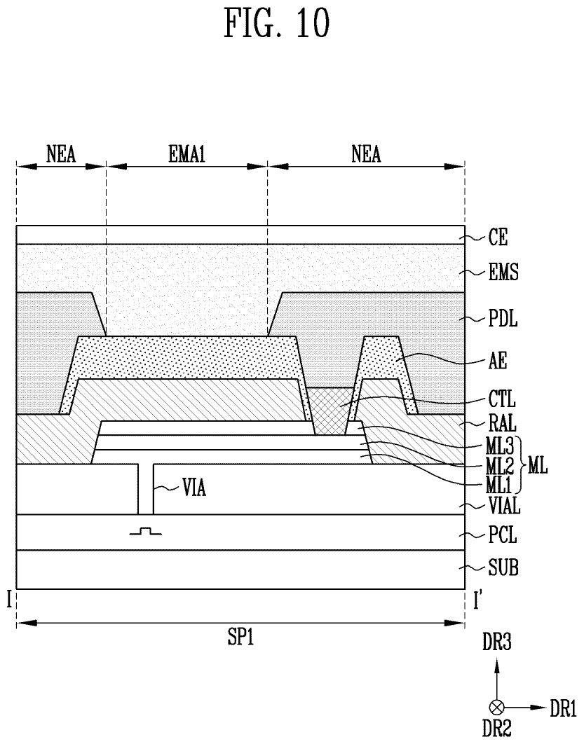

FIG. 10 is a sectional view taken along the line I-I′ shown in FIG. 7 according to some embodiments of the present disclosure. In FIG. 10, for clear and brief description, a sectional view of the first sub-pixel SP1 among the first to third sub-pixels SP1 to SP3 shown in FIG. 7 is schematically illustrated. The other sub-pixels may be configured identically to the sectional view of the first sub-pixel SP1.

Referring to FIG. 10, a substrate SUB and a pixel circuit layer PCL located on the substrate SUB are provided.

The substrate SUB may include a silicon wafer substrate formed using a semiconductor process. For example, the substrate SUB may include silicon, germanium, and/or silicon-germanium.

The pixel circuit layer PCL is located on the substrate SUB. The substrate SUB and the pixel circuit layer PCL may include circuit elements of the first sub-pixel SP1. For example, the substrate SUB and the pixel circuit layer PCL may include transistors and at least one capacitor of the first sub-pixel SP1. The substrate SUB and the pixel circuit layer PCL may include circuit elements of the second sub-pixel SP2 and circuit elements of the third sub-pixel SP3, which are shown in FIG. 7.

A via layer VIAL is located on the pixel circuit layer PCL. The via layer VIAL covers the pixel circuit layer PCL, and may have an entirely flat surface. The via layer VIAL is configured to planarize step difference on the pixel circuit layer PCL. The via layer VIAL may include at least one of silicon oxide (SiOₓ), silicon nitride (SiNₓ), and silicon carbon nitride (SiCN), but embodiments according to the present disclosure are not limited thereto. The via layer VIAL may include at least one via VIA.

On the via layer VIAL, a metal layer ML is located in the first sub-pixel SP1. On the via layer VIAL, the metal layer ML may be located in each of the second and third sub-pixels SP2 and SP3 shown in FIG. 7. The metal layer ML may be in contact with a circuit element located in the pixel circuit layer PCL through the via VIA penetrating the via layer VIAL.

The metal layer ML may serve as a full mirror which reflects light emitted from a light emitting structure EMS toward a display surface. For example, the metal layer ML may reflect light emitted from a rear surface to a front surface in the light emitting structure EMS overlapping the first emission area EMA. The metal layer ML may reflect light emitted from a rear surface to a front surface in a light emitting structure EMS overlapping with the second emission area EMA2 shown in FIG. 7. The metal layer ML may reflect light emitted from a rear surface to a front surface in a light emitting structure EMS overlapping with the third emission area EMA3 shown in FIG. 7.

The metal layer ML may include metal materials suitable for reflecting light. The metal layer ML may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments are not limited thereto.

According to some embodiments, the metal layer ML may have a multi-layer structure. For example, the metal layer ML may include a first metal layer ML1, a second metal layer ML2, and a third metal layer ML3.

The first metal layer ML1 is located on the via layer VIAL. The first metal layer ML1 may be electrically connected to a circuit element of the pixel circuit layer PCL through the via VIA. The first metal layer ML1 may improve an electrical connection characteristic between the second metal layer ML2 and the circuit element of the pixel circuit layer PCL. The first metal layer ML1 may include a metal material such as titanium (Ti), but embodiments according to the present disclosure are not limited thereto.

The second metal layer ML2 is located on the first metal layer ML1. The second metal layer ML2 may include a metal material which is suitable for reflecting light and has a high electrical conductivity. For example, an electrical conductivity of the second metal layer ML2 may be higher than an electrical conductivity of the third metal layer ML3. The second metal layer ML2 may include a metal material such as aluminum (Al), but embodiments according to the present disclosure are not limited thereto.

The third metal layer ML3 is located on the second metal layer ML2. The third metal layer ML3 is configured to planarize step differences cause by a hillock of the second metal layer ML2. The electrical conductivity of the third metal layer ML3 may be lower than the electrical conductivity of the second metal layer ML2. The third metal layer ML3 may include a metal material such as titanium nitride (TiN), but embodiments are not limited thereto.

A resonance auxiliary layer RAL is located on the via layer VIAL and the metal layer ML. The resonance auxiliary layer RAL may entirely cover the via layer VIAL, and partially cover the metal layer ML. That is, the resonance auxiliary layer RAL may expose a portion of the metal layer ML. For example, the resonance auxiliary layer RAL may expose a portion of a top surface of the third metal layer ML3. The resonance auxiliary layer RAL may include an inorganic material, but embodiments according to the present disclosure are not limited thereto.

The metal layer ML may serve as a full mirror, and a cathode electrode CE may serve as a half mirror. Light emitted from the light emitting structure EMS may be amplified by at least partially reciprocating between the metal layer ML and the cathode electrode CE, and the amplified light may be output through the cathode electrode CE. As such, a thickness between the metal layer ML and the cathode electrode CE may be understood as a resonance thickness of the light emitted from the light emitting structure EMS. The resonance auxiliary layer RAL may function to form an optimum resonance thickness with which the light emitted from the light emitting structure EMS is amplified. That is, the thickness of the resonance auxiliary layer RAL may be adjusted, thereby effectively and efficiently amplifying light in a specific wavelength range.

According to some embodiments, the thickness of the resonance auxiliary layer RAL may vary for each of the first to third sub-pixels SP1 to SP3 (see FIG. 7). Optimum resonance thicknesses with lights emitted from the respective light emitting structure EMS are amplified are different from one another. When the first to third sub-pixels SP1 to SP3 respectively correspond to red, green, and blue, a thickness of the resonance auxiliary layer RAL of the first sub-pixel SP1 may be thinner than a thickness of the resonance auxiliary layer RAL of the second sub-pixel SP2, and the thickness of the resonance auxiliary layer RAL of the second sub-pixel SP2 may be thinner than a thickness of the resonance auxiliary layer RAL of the third sub-pixel SP3. A resonance thickness of the first sub-pixel SP1 may be thinner than a resonance thickness of the second sub-pixel SP2, and the resonance thickness of the second sub-pixel SP2 may be thinner than a resonance thickness of the third sub-pixel SP3.

Anode electrodes AE overlapping with the metal layer ML are located on the resonance auxiliary layer RAL. Also, each of the anode electrodes AE is located on the metal layer ML exposed by the resonance auxiliary layer RAL. For example, each of the anode electrodes AE may be located on a portion of the top surface of the third metal layer ML3, which is exposed by the resonance auxiliary layer RAL.

The anode electrodes AE may be connected to the metal layer ML through a contact layer CTL penetrating the metal layer ML. For example, the anode electrodes AE may be connected to the second metal layer ML2 through the contact layer CTL penetrating the third metal layer ML3. The anode electrodes AE adjacent to the contact layer CTL may have a doughnut shape. For example, each of the anode electrodes AE, which is located on a portion of the top surface of the third metal layer ML3, may have a hole penetrating the center thereof.

According to some embodiments, the anode electrodes AE may include at least one of transparent conductive materials such as indium tin oxide (ITO), indium zinc oxide (IZO), zinc oxide (ZnO), indium gallium zinc oxide (IGZO), and indium tin zinc oxide (ITZO). However, embodiments according to the present disclosure are not limited thereto.

The contact layer CTL is located on the metal layer ML. The contact layer CTL may be electrically connected to the anode electrodes AE. The contact layer CTL may partially penetrate the metal layer ML. According to some embodiments, the contact layer CTL may penetrate the third metal layer ML3 such that the second metal layer ML2 is exposed. The contact layer CTL may be in contact with a top surface of the second metal layer ML2 while penetrating the third metal layer ML3, but embodiments are not limited thereto. For example, the contact layer CTL may partially penetrate not only the third metal layer ML3 but also the second metal layer ML2. The contact layer CTL may electrically connect the second metal layer ML2 having the electrical conductivity higher than the electrical conductivity of the third metal layer ML3 to the anode electrodes AE, thereby improving an electrical connection characteristic between the anode electrodes AE and the metal layer ML. Further, the contact layer CTL can reduce or prevent a problem occurring due to a disconnection between the metal layer ML and the anode electrodes AE adjacent to the resonance auxiliary layer RAL or an increase in resistance according to a decrease in thickness. Thus, electrical characteristics of the display device 100 (see FIG. 1) can be improved.

The contact layer CTL may include at least one of aluminum (Al), tungsten (W), silver (Ag), magnesium (Mg), platinum (Pt), palladium (Pd), gold (Au), nickel (Ni), neodymium (Nd), iridium (Ir), chromium (Cr), and titanium (Ti). However, embodiments according to the present disclosure are not limited thereto.

A pixel defining layer PDL is arranged over portions of the anode electrodes AE, the resonance auxiliary layer RAL, and the contact layer CTL. The pixel defining layer PDL may include an opening OP (see FIG. 4) exposing a portion of each of the anode electrodes AE. The opening OP of the pixel defining layer PDL may define an emission area of each of the first to third sub-pixels SP1 to SP3 (see FIG. 7). As such, the pixel defining layer PDL may define the first to third emission areas EMA1 to EMA3 shown in FIG. 7 while being located in the non-emission area NEA.

According to some embodiments, the pixel defining layer PDL may include a plurality of inorganic insulating layers. Each of the plurality of inorganic insulating layers may include at least one of silicon oxide (SiOₓ) and silicon nitride (SiNₓ). For example, the pixel defining layer PDL may include first to third inorganic insulating layers which are sequentially stacked, and each of the first to third inorganic insulating layers may include silicon nitride, silicon oxide, and silicon oxynitride. However, embodiments according to the present disclosure are not limited thereto.

The light emitting structure EMS may be located on the anode electrodes AE exposed by the opening OP (see FIG. 4) of the pixel defining layer PDL. The light emitting structure EMS fills the opening OP of the pixel defining layer PDL, and may be entirely arranged throughout the first sub-pixel SP1. The light emitting structure EMS fills the opening OP of the pixel defining layer PDL, and may be entirely arranged throughout the second and third sub-pixels SP2 and SP3 shown in FIG. 7.

The cathode electrode CE is located on the light emitting structure EMS. The cathode electrode CE may be commonly provided in the first to third sub-pixels SP1 to SP3 (see FIG. 7). The cathode electrode CE may serve as a half mirror which allows light emitted from the light emitting structure EMS to be partially transmitted therethrough and to be partially reflected therefrom.

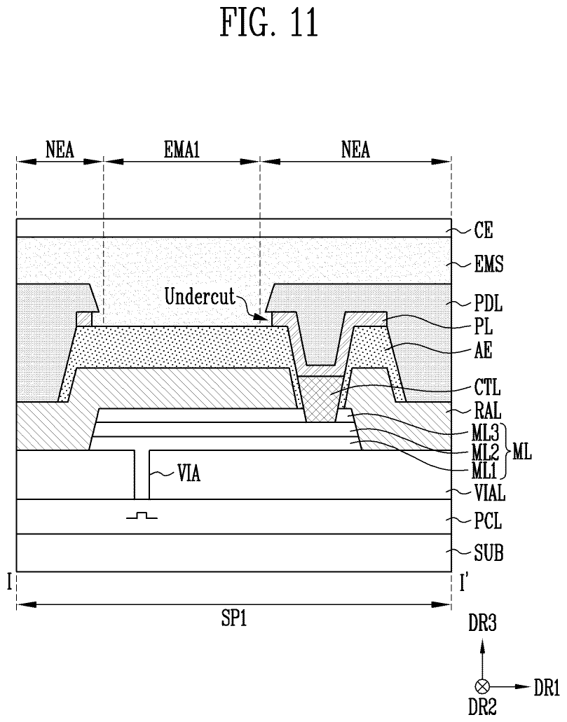

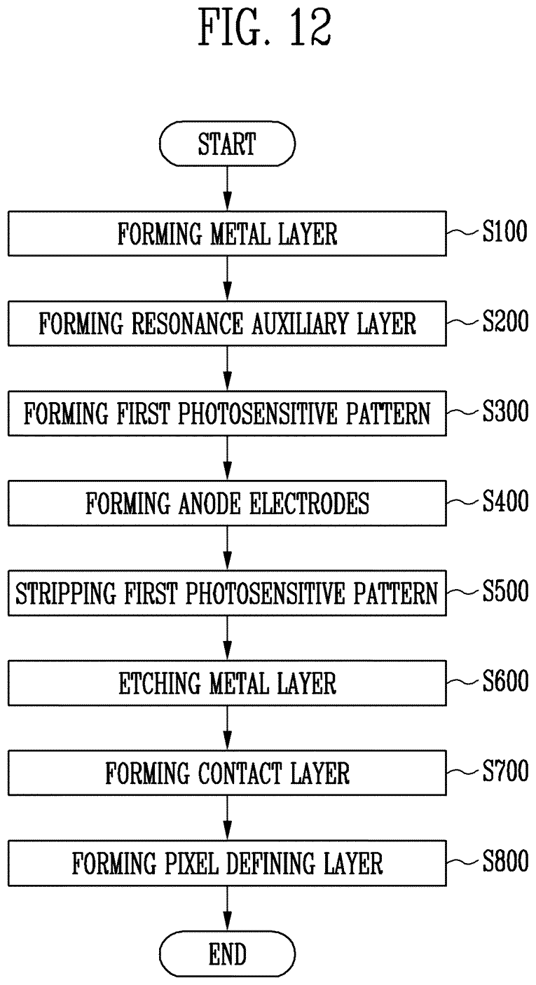

FIG. 11 is a sectional view taken along the line I-I′ shown in FIG. 7 according to some embodiments of the present disclosure. In FIG. 11, for clear and brief description, a sectional view of the first sub-pixel SP1 among the first to third sub-pixels SP1 to SP3 shown in FIG. 7 is schematically illustrated. The other sub-pixels may be configured identically to the sectional view of the first sub-pixel SP1. In relation to FIG. 11, descriptions of portions overlapping with those shown in FIG. 10 will be omitted or simplified.

Referring to FIG. 11, a protective layer PL is located on portions of the contact layer CTL and the anode electrode AE. The protective layer PL may include a transparent metal oxide. For example, the protective layer PL may include at least one of indium zinc oxide (IZO) and indium gallium zinc oxide (IGZO), but embodiments according to the present disclosure are not limited thereto. The protective layer PL may include an opening exposing one surface of each of the anode electrodes AE. The protective layer PL may protect the anode electrode AE when the opening OP (see FIG. 4) of the pixel defining layer PDL is formed.

The pixel defining layer PDL is located on the resonance auxiliary layer RAL, portions of the anode electrodes AE, the protective layer PL, and portions of the light emitting structure EMS. The pixel defining layer PDL may have an undercut structure due to the protective layer PL. Accordingly, the light emitting structure EMS may be at least cut or bent. For example, as a p-hole injection layer doped with a p-type dopant included in the light emitting structure EMS is cut or bent, a discontinuous portion may be formed in the light emitting structure EMS.

In addition, when the light emitting structure EMS has a tandem structure including two or more light emitting units, a discontinuous portion may be formed in the light emitting structure EMS as the charge generation layer CGL (see FIG. 5) included in the light emitting structure EMS is cut or bent. Accordingly, a current (or leakage current) leaked from each of the first to third sub-pixels SP1 to SP3 (see FIG. 7) to sub-pixels adjacent thereto through layers included in the light emitting structure EMS can be reduced.

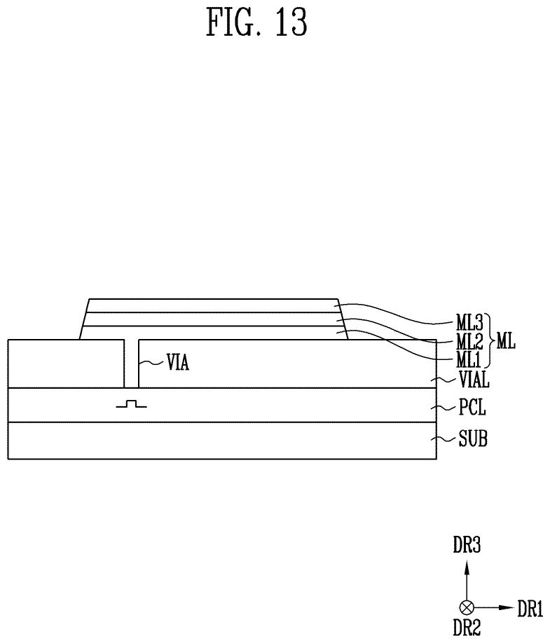

FIG. 12 is a flowchart illustrating a manufacturing method of the display device according to some embodiments of the present disclosure. Although various operations are illustrated in FIG. 12, embodiments according to the present disclosure are not limited thereto. For example, according to some embodiments, a method of manufacturing a display device may include additional operations or fewer operations, or the order of operations may vary (unless otherwise expressly stated or implied), without departing from the spirit and scope of embodiments according to the present disclosure. FIGS. 13 to 20 are sectional views schematically illustrating aspects of the manufacturing method shown in FIG. 12 according to some embodiments of the present disclosure.

Referring to FIG. 12, the manufacturing method of the display device may include operation S100 of forming a metal layer, operation S200 of forming a resonance auxiliary layer, operation S300 of forming a first photosensitive pattern, operation S400 of forming anode electrodes, operation S500 of stripping the first photosensitive pattern, operation S600 of etching the metal layer, operation S700 of forming a contact layer, and operation S800 of forming a pixel defining layer.

Referring to FIGS. 12 and 13, a metal layer ML is formed (S100). For example, the metal layer ML may be formed on a via layer VIAL located on a pixel circuit layer PCL located on a substrate SUB. According to some embodiments, the metal layer ML having a multi-layer structure may be formed by forming a first metal layer ML1 connected to a via VIA on the via layer VIAL, forming a second metal layer ML2 on the first metal layer ML1, and forming a third metal layer ML3 on the second metal layer ML2.

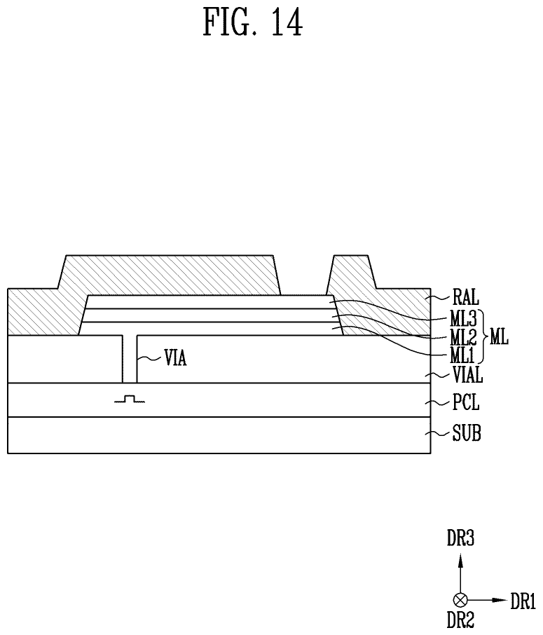

Referring to FIGS. 12 and 14, a resonance auxiliary layer RAL is formed (S200). For example, the resonance auxiliary layer RAL may be formed on the via layer VIAL and portions of the metal layer ML. After the resonance auxiliary layer RAL is formed on the via layer VIAL and the metal layer ML, a portion of a top surface of the third metal layer ML3 may be exposed by partially etching the resonance auxiliary layer RAL. In addition, step differences may be in the resonance auxiliary layer RAL by partially etching the resonance auxiliary layer RAL.

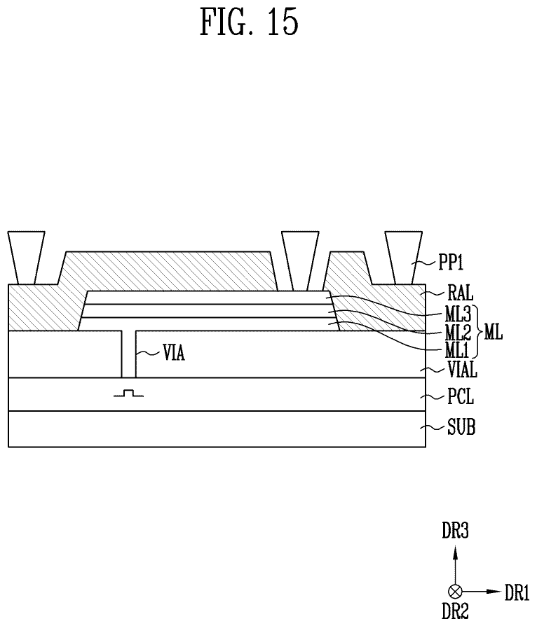

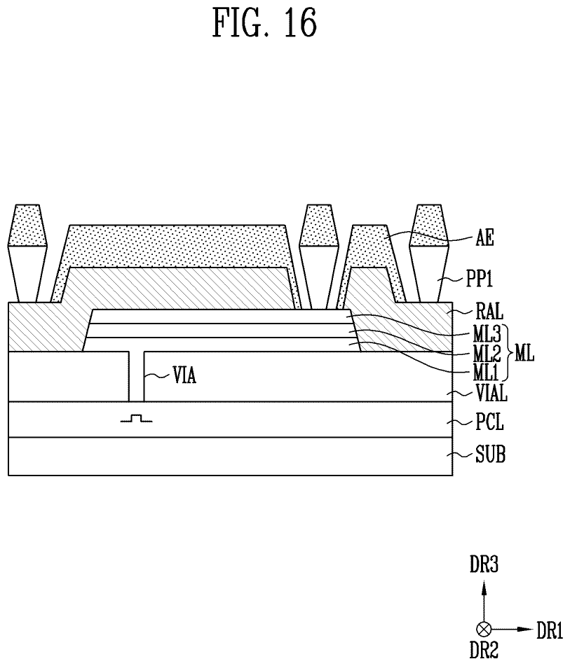

Referring to FIGS. 12 and 15, a first photosensitive pattern PP1 is formed (S300). For example, a first photosensitive pattern PP1 may be formed on the partially etched resonance auxiliary layer RAL and the third metal layer ML3 exposed by the resonance auxiliary layer RAL. The first photosensitive pattern PP1 may be patterned by applying a photosensitive material on the resonance auxiliary layer RAL and the third metal layer ML3 and then light-exposing and developing the applied photosensitive material. According to some embodiments, the first photosensitive pattern PP1 may be patterned to have a reverse tapered shape. This is for the purpose of patterning anode electrodes AE (see FIG. 16) which will be described later at desired positions.

Referring to FIGS. 12 and 16, the anode electrodes AE are formed (S400). For example, the anode electrodes AE may be formed on portions of the resonance auxiliary layer RAL and portions of the third metal layer ML3. Also, each of the anode electrodes AE may be formed on the first photosensitive pattern PP1. That is, the anode electrodes AE may not be formed on the resonance auxiliary layer RAL and the third metal layer ML3, each of which overlaps with the first photosensitive pattern PP1 having the reverse tapered shape.

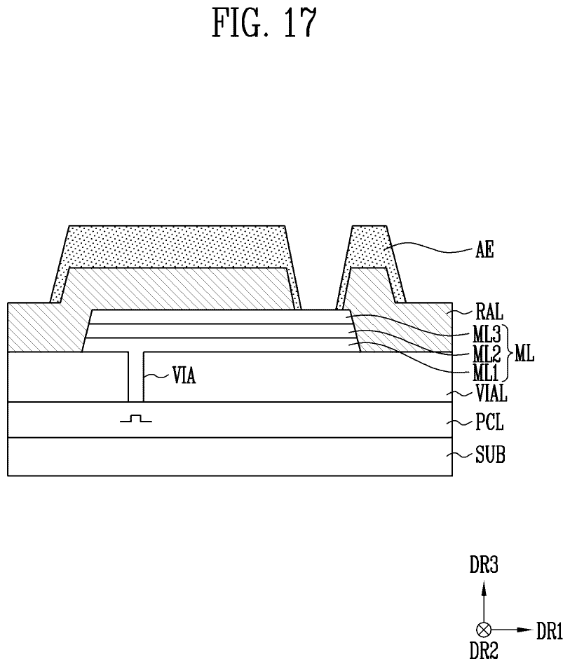

Referring to FIGS. 12 and 17, the first photosensitive pattern PP1 is stripped (S500). For example, the remaining first photosensitive pattern PP1 (see FIG. 16) may be stripped and removed. In this process, the anode electrodes AE on the first photosensitive pattern PP1 may be removed together with the first photosensitive pattern PP1. Accordingly, anode electrodes AE overlapping with the metal layer ML may be formed on the resonance auxiliary layer RAL. In addition, anode electrodes AE having a doughnut shape may be formed on the third metal layer ML3.

Referring to FIGS. 15 to 17, the anode electrodes AE can be readily patterned in a desired pattern without any etching process. That is, the anode electrodes AE can be readily patterned in the desired pattern through a lift-off process using the first photosensitive pattern PP1.

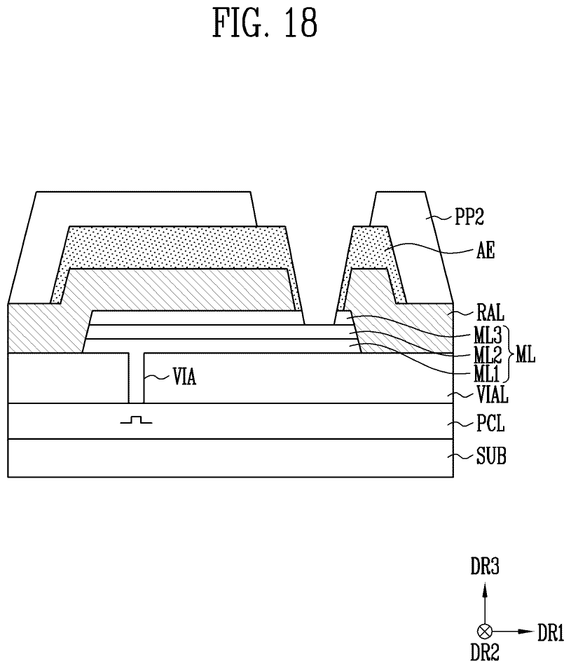

Referring to FIGS. 12 and 18, the metal layer ML is etched (S600). For example, the third metal layer ML3 may be etched such that the second metal layer ML2 is exposed. For example, a second photosensitive pattern PP2 is patterned by applying a photosensitive material on the resonance auxiliary layer RAL and the anode electrodes AE and then light-exposing and developing the applied photosensitive material. After that, the third metal layer ML3 may be etched using, as a mask, the second photosensitive pattern PP2 and the anode electrodes AE. As such, the anode electrode AE extending to the resonance auxiliary layer RAL on the third metal layer ML3 may serve as a hard mask. Unlike as shown in FIG. 18, the second metal layer ML2 may be exposed by partially further etching the second metal layer ML2.

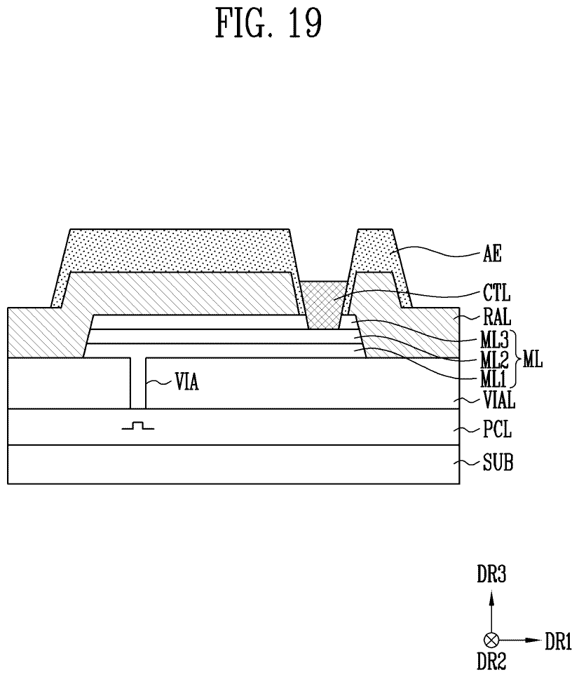

Referring to FIGS. 12 and 19, a contact layer CTL is formed (S700). For example, the contact layer CTL may be formed on the second metal layer ML2. The contact layer CTL may be deposited to a thickness (e.g., a set or predetermined thickness) on the second metal layer ML2 to be connected to the anode electrodes AE. The anode electrodes AE may be connected to the second metal layer ML2 having an electrical conductivity relatively higher than an electrical conductivity of the third metal layer ML3 through the contact layer CTL. Thus, an electrical connection characteristic between the anode electrodes AE and the metal layer ML can be improved.

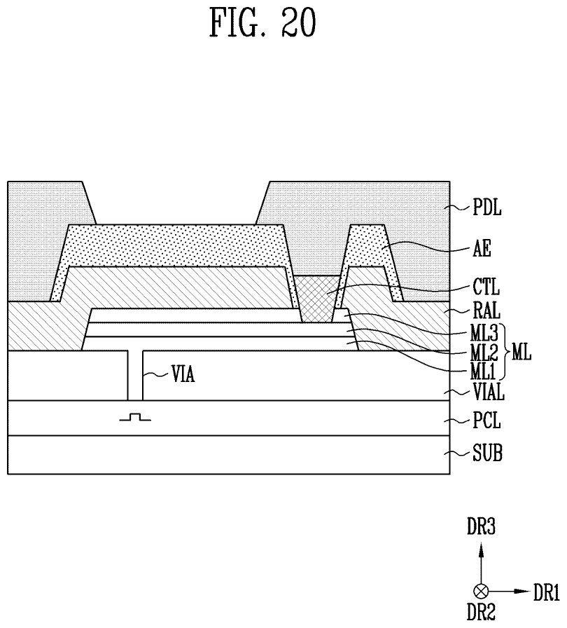

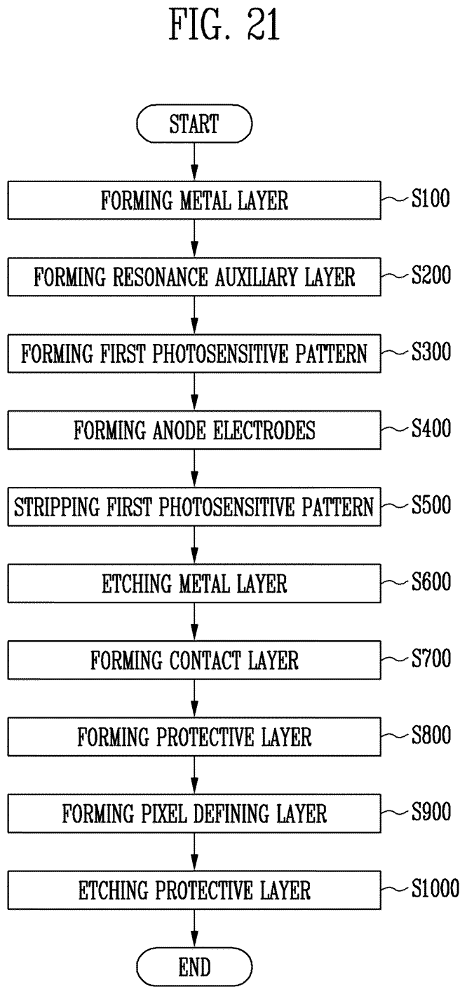

Referring to FIGS. 12 and 20, a pixel defining layer PDL is formed (S800). For example, the pixel defining layer PDL may be formed on the resonance auxiliary layer RAL, portions of the anode electrodes AE, and the contact layer CTL. The pixel defining layer PDL may be formed on the portions of the anode electrodes AE to expose the anode electrodes AE.

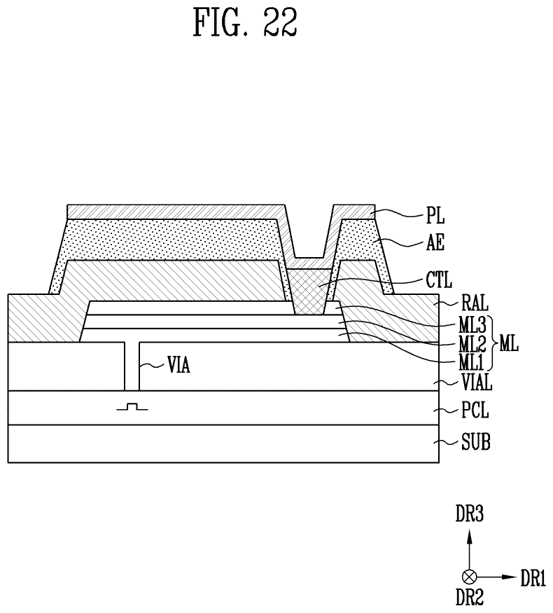

FIG. 21 is a flowchart illustrating a manufacturing method of the display device according to some embodiments of the present disclosure. Although various operations are illustrated in FIG. 21, embodiments according to the present disclosure are not limited thereto. For example, according to some embodiments, a method of manufacturing a display device may include additional operations or fewer operations, or the order of operations may vary (unless otherwise expressly stated or implied), without departing from the spirit and scope of embodiments according to the present disclosure. In relation to FIG. 21, descriptions of portions overlapping with those shown in FIGS. 12 to 20 will be simplified or omitted. FIGS. 22 to 24 are sectional views schematically illustrating operations S800 to S1000 in the manufacturing method shown in FIG. 21 according to some embodiments of the present disclosure.

Referring to FIG. 21, the manufacturing method of the display device may include operation S100 of forming a metal layer, operation S200 of forming a resonance auxiliary layer, operation S300 of forming a first photosensitive pattern, operation S400 of forming anode electrodes, operation S500 of stripping the first photosensitive pattern, operation S600 of etching the metal layer, operation S700 of forming a contact layer, operation S800 of forming a protective layer, operation S900 of forming a pixel defining layer, and operation S1000 of etching the protective layer.

Referring to FIGS. 21 and 22, a protective layer PL is formed (S800). For example, the protective layer PL may be formed on the anode electrodes AE and the contact layer CTL. The protective layer PL may be patterned to cover flat surfaces of the anode electrodes AE.

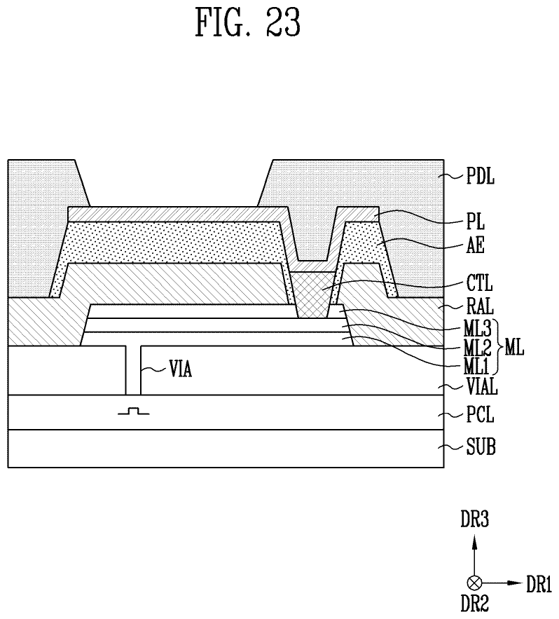

Referring to FIGS. 21 and 23, a pixel defining layer PDL is formed (S900). For example, the pixel defining layer PDL may be formed on the resonance auxiliary layer RAL, the anode electrodes AE, and portions of the protective layer PL. For example, after the pixel defining layer PDL is formed on the resonance auxiliary layer RAL, the anode electrodes AE, and the protective layer PL, the protective layer PL may be exposed by partially etching the pixel defining layer PDL. That is, the pixel defining layer PDL may be etched until the protective layer PL is exposed. The protective layer PL may serve as an etching stopper, thereby preventing a top surface of each of the anode electrodes AE from being damaged in a process of etching the pixel defining layer PDL.

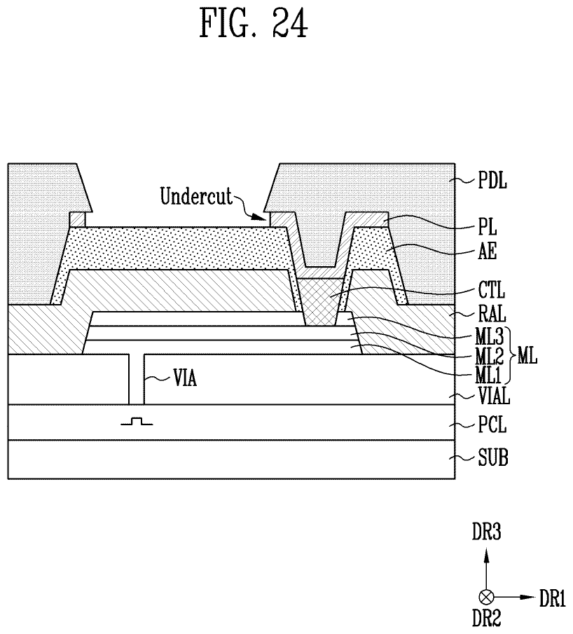

Referring to FIGS. 21 and 24, the protective layer PL is etched (S1000). For example, the protective layer PL may be partially etched such that the pixel defining layer PDL has an undercut structure. Accordingly, the protective layer PL exposing the anode electrodes AE may be formed. When the pixel defining layer PDL has the undercut structure, a leakage current can be prevented from flowing between adjacent sub-pixels as a p-hole injection layer or a charge generation layer CGL (see FIG. 5), which is included in a light emitting structure EMS (see FIG. 11) located on the anode electrodes AE, is cut or bent.

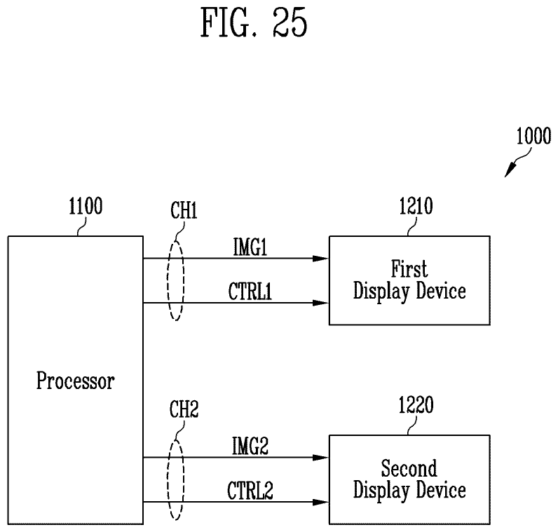

FIG. 25 is a block diagram illustrating a display system according to some embodiments of the present disclosure.

Referring to FIG. 25, a display system 1000 may include a processor 1100 and first to second display devices 1210 and 1220.

The processor 1100 may perform various tasks and various calculations. According to some embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

In FIG. 25, it is illustrated that the display system 1000 includes first and second display devices 1210 and 1220. The processor 1100 may be connected to the first display device 1210 through a first channel CH1, and be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured identically to the display device 100 described with reference to FIG. 1. The first image data IMG1 and the first control signal CTRL1 may be respectively provided as the input image data IMG and the control signal CTRL, which are shown in FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device 100 described with reference to FIG. 1. The second image data IMG2 and the second control signal CTRL2 may be respectively provided as the image data IMG and the control signal CTRL, which are shown in FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

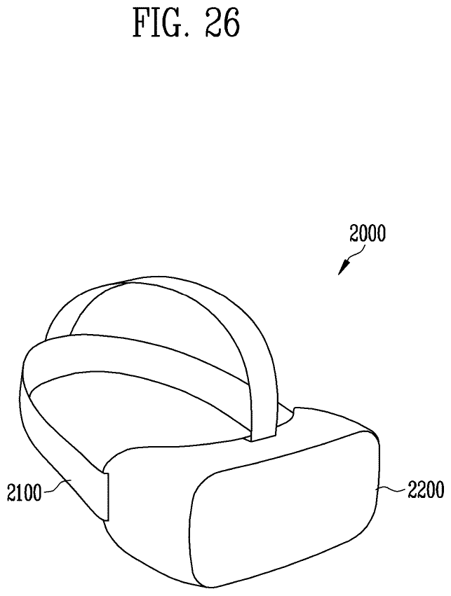

FIG. 26 is a perspective view illustrating an application example of the display system shown in FIG. 25 according to some embodiments of the present disclosure.

Referring to FIG. 26, the display system 1000 shown in FIG. 25 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments of the present disclosure are not limited thereto. For example, the head mounting band 2100 may be implemented in the form of a glasses frame, a helmet or the like.

The display device accommodating case 2200 may accommodate the first and second display devices 1210 and 1220 shown in FIG. 25. The display device accommodating case 2200 may further accommodate the processor 1100 shown in FIG. 25.

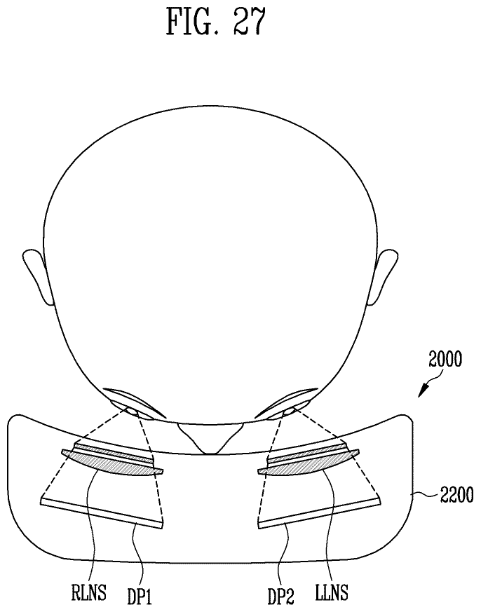

FIG. 27 is a view illustrating the head-mounted display device shown in FIG. 26, which is worn by a user according to some embodiments of the present disclosure.

Referring to FIG. 27, a first display panel DP1 of the first display device 1210 and a second display panel DP2 of the second display device 1220 may be located in the head mounted display device 2000. The head mounted display device 2000 may further include a left-eye lens LLNS and a right-eye lens RLNS.

In the display device accommodating case 2200, a right-eye lens RLNS may be located between the first display panel DP1 and a right eye of the user. In the display device accommodating case 2200, a left-eye lens LLNS may be located between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

According to some embodiments, each of the right-eye lens RLNS and the left-eye lens LLNS may include an optical lens having a pancake-shaped section. According to some embodiments, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

The embodiments described in detail above are provided to explain the present disclosure, but these embodiments are not intended to limit the scope of the present disclosure. It should be understood by those skilled in the art that various changes, substitutions, and alternations may be made therein without departing from the scope of the disclosure as defined by the following claims and their equivalents.

The scope of embodiments according to the present disclosure is not limited by detailed descriptions of the present specification and should be defined by the accompanying claims and their equivalents. Furthermore, all changes or modifications of embodiments according to the present disclosure derived from the claims, and equivalents thereof, should be construed as being included in the scope of embodiments according to the present disclosure. The embodiments may be combined to form additional embodiments.

What is claimed is:

1. A display device comprising:
a metal layer on a via layer, the metal layer overlapping with emission areas;
a resonance auxiliary layer on the via layer and the metal layer, the resonance auxiliary layer exposing the metal layer;
anode electrodes on the resonance auxiliary layer; and
a contact layer connected to the metal layer and the anode electrodes.

2. The display device of claim 1, wherein the metal layer includes:
a first metal layer connected to a via of the via layer;
a second metal layer on the first metal layer; and
a third metal layer on the second metal layer.

3. The display device of claim 2, wherein an electrical conductivity of the second metal layer is higher than an electrical conductivity of the third metal layer.

4. The display device of claim 3, wherein the contact layer is connected to the second metal layer and penetrates the third metal layer.

5. The display device of claim 1, further comprising a pixel defining layer on the resonance auxiliary layer, the anode electrodes, and the contact layer, the pixel defining layer exposing the anode electrodes.

6. The display device of claim 1, further comprising a protective layer on the anode electrodes and the contact layer, the protective layer exposing the anode electrodes.

7. The display device of claim 6, further comprising a pixel defining layer on the resonance auxiliary layer, the anode electrodes, and the protective layer, the pixel defining layer having an undercut structure.

8. The display device of claim 1, wherein the resonance auxiliary layer includes an inorganic material.

9. The display device of claim 1, wherein the contact layer includes a metal material.

10. A method of manufacturing a display device, the method comprising:
forming a metal layer on a via layer;
forming a resonance auxiliary layer exposing the metal layer on the via layer and the metal layer;
forming a first photosensitive pattern on the resonance auxiliary layer and the exposed metal layer;
forming anode electrodes on the resonance auxiliary layer and the first photosensitive pattern;
stripping the first photosensitive pattern; and
forming a contact layer penetrating the metal layer.

11. The method of claim 10, wherein forming the metal layer includes:
forming a first metal layer connected to a via of the via layer;
forming a second metal layer on the first metal layer; and
forming a third metal layer on the second metal layer.

12. The method of claim 11, wherein an electrical conductivity of the second metal layer is higher than an electrical conductivity of the third metal layer.

13. The method of claim 10, wherein the first photosensitive pattern is formed in a reverse tapered shape.

14. The method of claim 11, wherein forming the contact layer includes:
forming a second photosensitive pattern on the resonance auxiliary layer and the anode electrodes;
etching the third metal layer such that the second metal layer is exposed;
stripping the second photosensitive pattern; and
forming the contact layer to be connected to the anode electrodes on the exposed second metal layer.

15. The method of claim 10, further comprising forming a pixel defining layer exposing the anode electrodes on the resonance auxiliary layer, the anode electrodes, and the contact layer.

16. The method of claim 10, further comprising forming a protective layer on the contact layer and the anode electrodes.

17. The method of claim 16, further comprising forming a pixel defining layer exposing the protective layer on the resonance auxiliary layer, the anode electrodes, and the protective layer.

18. The method of claim 17, further comprising etching the protective layer such that the pixel defining layer has an undercut structure.

19. The method of claim 10, wherein the resonance auxiliary layer includes an inorganic material.

20. The method of claim 10, wherein the contact layer includes a metal material.
